(19) United States
(12) Patent Application Publication
(10) Pub. No.: US 2014/0050240 A1
(43) Pub. Date: Feb. 20, 2014

(54) Vertical-Cavity Surface-Emitting Laser with a Mode Control Cavity and an Undercut Structure

(71) Applicants: Jin-Wei Shi, Taipei (TW); Ying-Jay Yang, Taipei (TW)

(72) Inventors: Jin-Wei Shi, Taipei (TW); Ying-Jay Yang, Taipei (TW)

(21) Appl. No.: 13/666,302

(22) Filed: Nov. 1, 2012

(30) Foreign Application Priority Data
Aug. 16, 2012 (TW) 101130064

(51) Int. Cl. H01S 5/187; H01S 5/34

(52) U.S. Cl. 372/45.01

(57) ABSTRACT

A new vertical-cavity surface-emitting laser (VCESL) is provided. With an undercut structure and a diffusion structure, the VCESL obtains a controllable number of optical modes for a distributed Bragg reflector (DBR). Thus, an electrical-to-optical bandwidth and a bit-rate transmission distance in OM4 fiber reach their biggest values. Besides, a biggest D-coefficient (˜13.5 GHz/mA^{1/2}), a smallest energy-data rate under 34 Gbit/s (EDR:140 fJ/bit) and a smallest energy-data distance rate under 25 Gbit/s with 0.8 km of OM4 fiber (EDDR:175.5 fJ/bit·km) are obtained.

### TECHNICAL FIELD OF THE INVENTION

The present invention relates to vertical-cavity surface-emitting laser (VCSEL); more particularly, relates to a VCSEL having a mode control cavity to control the number of lasing modes, which is formed above a light emitting region located around a center area on top of a distributed Bragg reflector (DBR), and an undercut structure to confine the current, which is formed by a selective etching in the layer just above or below the active layer. The mode control cavity is obtained from a multi-layer selectively disordered through doping and diffusing; where a higher modulation speed is achieved; and where an electrical-to-optical (E-O) bandwidth and a bit-rate transmission distance in OM4 fiber reach their largest values.

### DESCRIPTION OF THE RELATED ARTS

A high-speed, high-performance and low-power-consumption VCSEL having an 850 nanometers (nm) or 1310 nm wavelength is used in optical interconnects (OI). As comparing to a prior art of edge-emitting distributed feed-back (DFB) laser used in 1.3-micrometers (μm) OI, the 850 nm or 1310 nm VCSEL only consumes about one tenth power under an operation of 25 gigabits per second (Gbit/s).

On considering power consumption of the high-speed VCSEL, there are two critical parameters, which are current modulation efficiency (D-coefficient) and threshold current (Iₜₕ). Under a big D-coefficient and a small Iₜₕ, a faster modulation speed can be achieved with a smaller bias current. In another word, less power is thus consumed by a high-speed VCSEL.

For further improving performance of the high-speed VCSEL by decreasing the Iₜₕ and increasing the D-coefficient, there are two main methods: one is to use multiple quantum wells (MQWs) having pressure stress for increasing differential gain of light emitting layer and improving the D-coefficient. In the other hand, for further enhancing modulation speed of the VCSEL, an oxide multi-layer is used to reduce a high parasitic capacitance of an oxide-confined VCSEL. Hence, the other method is to greatly reduce size of an oxidation aperture for decreasing a threshold current. Recently, an 850 nm single-mode VCSEL can be operated under 17 Gbit/s at a room temperature (83 femtojoule per bit [fJ/bit]). However, as comparing to the bigger oxidation aperture of the high-performance 850 nm VCSEL, its biggest 3-dB E-O bandwidth is obviously a decreased one (23 vs 13 Gbit/s). The reason for the reduced speed may be the greatly increased differential resistance of the VCSEL (about 570 ohm [Ω], which is much larger compared to that of the other VCSELs). This kind of small aperture (about 2 μm) and the single-mode output may cause spatial hole burning effect and relaxation oscillation (RO) frequency; and may further limit the E-O bandwidth. Besides, when the current threshold further makes the oxidation aperture smaller, stress on layers above a light emitting region may harm reliability of the VCSEL. Nevertheless, an isolation layer on top of a distributed Bragg reflector (DBR) may increase resistance, conductive voltage and power consumption of the VCSEL; and may limit its high-speed performance when being operated under a high temperature.

Although reducing the size of the oxidation aperture (the current threshold) is an effective way for decreasing power consumption on high-speed operation, the VCSEL may obtain a high differential resistance, a single-mode output and a small output power, which may seriously limit the E-O bandwidth and its reliability. Hence, the prior arts do not fulfill all users' requests on actual use.

### SUMMARY OF THE INVENTION

The main purpose of the present invention is to provide a VCSEL having a mode control cavity to control the number of lasing modes and an undercut structure to confine the current, where the mode control cavity is formed above a light emitting region located around a center area on top of a distributed Bragg reflector (DBR), and is obtained from a multi-layer selectively disordered through diffusing; the undercut structure is formed by selective wet etching and confines the current flowing through a small aperture to form an active region; a device performance of a high speed and low power consumption is thus obtained; and an E-O bandwidth and a bit-rate transmission distance in OM4 fiber reach their largest values by controlling the number of lasing modes in resonant cavity.

Another purpose of the present invention is to provide a VCSEL having a good dynamic performance with a best Zn diffusion depth and an aperture size of about 5 um to have a single mode operation.

Another purpose of the present invention is to provide a VCSEL having a biggest D-coefficient (˜13.5 GHz/mA^{1/2}), a smallest energy-data rate under 34 Gbit/s (EDR:140 fJ/bit) and a smallest energy-data distance rate under 25 Gbit/s with an 0.8 kilometers (km) OM4 fiber (EDDR:175.5 fJ/bit·km).

To achieve the above purposes, the present invention is a VCSEL having a controllable number of optical modes, comprising a substrate and an extended structure, where the extended structure is grown on the substrate; the extended structure comprises a first DBR, a light emitting region grown on the first DBR, and a second DBR grown on the light emitting region; the light emitting region has an undercut structure; the undercut structure is located above the light emitting region or below the light emitting region; the undercut structure has an composite layer; a lateral part of a composite layer is etched to form a central current-confined area; the composite layer contains a III/V group element having a content rate more than 20 percents (%); and the III/V group element is aluminum (Al); the second DBR has a mode control cavity, which is formed by selective diffusion in the periphery around a central area above a light emitting region, and the multi-layer in periphery is totally disordered by diffusing to form a single layer, while the central area as an optical aperture remains intact. Accordingly, a novel VCSEL with a mode control cavity having a central optical aperture to control the number of lasing modes is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the sectional view showing the preferred embodiment according to the present invention;

FIG. 2 is the top-down view showing the preferred embodiment;

FIG. 3 is the view showing the first spectrums; and

FIG. 4 is the view showing the second spectrums.

### DESCRIPTION OF THE PREFERRED EMBODIMENT

The following description of the preferred embodiment is provided to understand the features and the structures of the present invention.

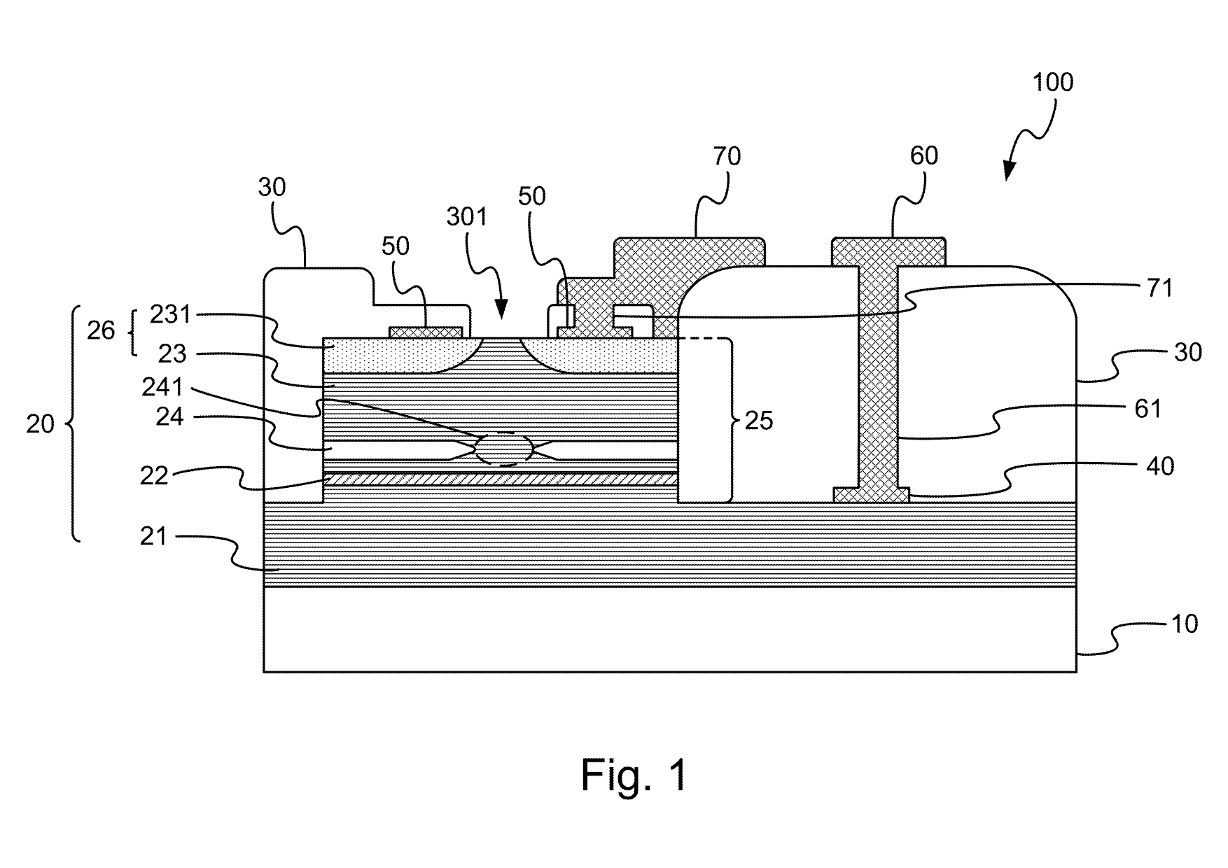

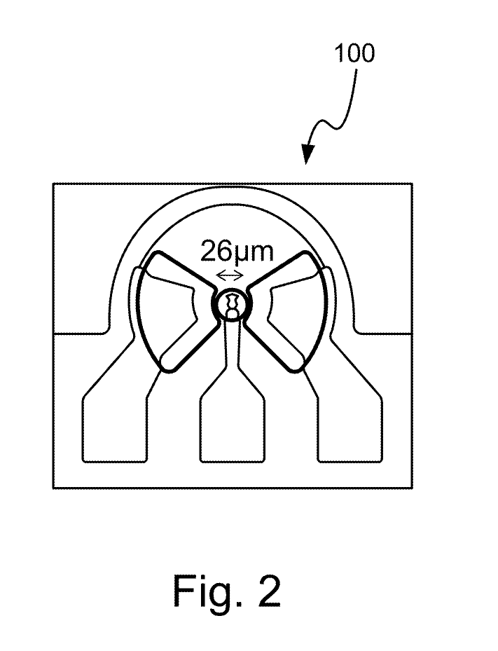

Please refer to FIG. 1 and FIG. 2, which are a sectional view and a top-down view showing a preferred embodiment according to the present invention. As shown in the figures, the present invention is a vertical-cavity surface-emitting laser (VCSEL) 100 having a mode control cavity 26 to control number of lasing modes, comprising a substrate 10, an extended structure 20, an insulation layer (Bisbenzocyclobutene, BCB) 30, an n-type contact (N contact) 40, a p-type contact (P contact) 50, an n-type metal pad 60 and a p-type metal pad 70.

The substrate 10 can be made of gallium arsenide (GaAs), indium phosphide (InP), aluminum nitride (AlN), indium nitride (InN) or silicon (Si).

The extended structure 20 is stacked on the substrate 10 and comprises a first DBR 21, the light emitting region 22 (active region) on the first DBR 21, and a second DBR 23 on the light emitting region 22. The light emitting region 22 can further be a structure of multiple quantum wells (MQWs) between the first DBR 21 and the second DBR 23; and, the MQWs structure is a heterojunction consisting of a compound semiconductor and an alloy of the compound semiconductor. Then, the extended structure 20 is grown and a mesa 25 is formed through chemical etching. Therein, the mesa 25 comprises a part of the first DBR 21; the light emitting region 22; the second DBR 23; and a undercut structure 24. The undercut structure 24 is located above the light emitting region 22 and is not contact with the light emitting region 22. The undercut structure 24 grows a composite layer at first; and, then, a lateral part is etched to define a central current-confined area 241. The undercut structure 24 has a diameter smaller than 5 micrometers (μm); and, the Al composite layer contains an group III element, aluminum (Al), more than 20 percents (%). The undercut structure 24 is formed through selective etching. The undercut structure 24 has a distance to the light emitting region 22 at least more than 100 nm. The second DBR 23 includes the diffusion structure 231. The diffusion structure 231 surrounding a light emitting aperture 301 is located on top of the second DBR 23 and is a single layer obtained from a multi-layer selectively disordered through diffusion. Thus, the second DBR 23 obtains a mode control cavity 26, which comprises the diffusion structure 231, the light emitting aperture 301, and a part of the second DBR 23, to control the number of lasing modes.

The insulation layer 30 has a light emitting aperture 301. The light emitting aperture 301 is extended from two ends to hold the second DBR 23, the light emitting region 22 and a part of the first DBR 21 for holding the undercut structure 24 within the area defined by the extension from the two ends of the insulation layer 30. Thus, center of the light emitting aperture 30 is focused on the central current-confined area 241. Therein, the second DBR 23 is surrounded by the insulation layer 30, the light emitting region 22 and the first DBR 21.

The N contact 40 is buried in the insulation layer and is located on the interface of the insulation layer 30 and the first DBR 21.

The P contact 50 is buried in the insulation layer and is located on the interface of the insulation layer 30 and the second DBR 23.

The n-type metal pad 60 is formed on the insulation layer 30 and is electrically connected with the N contact 40 through a penetrating hole 61 in the insulation layer 30.

The p-type metal pad 70 is formed on the insulation layer 30 and is electrically connected with the P contact 50 through another penetrating hole 71 in the insulation layer 30.

The light emitting region 22 is sandwiched between the first DBR 21 and the second DBR 23.

The undercut structure 24 can also be located below the light emitting region 24.

The first DBR 21 is an n-type DBR (n-DBR) and the second DBR 23 is a p-type DBR (p-DBR); or, the first DBR 21 is a p-type DBR (p-DBR) and the second DBR 23 is an n-type DBR (n-DBR)

On using the present invention, there is a circling area having a diameter of 26 μm, as shown in FIG. 2, which can be integrated with a pad of co-planar waveguide (CPW) for on-wafer high-speed detection.

In a use of the preferred embodiment, the Al composite layer is partially removed through selective wet etching while center area of the Al composite layer is kept unchanged, to obtain the undercut structure 24 and the current-confined area 241.

In a use of the preferred embodiment, the Al composite layer can be partially transferred into an oxide layer while center area of the Al composite layer is kept unchanged. Then, the oxide layer is removed through selective wet etching to obtain the undercut structure 24 and the current-confined area 241.

In a use of the preferred embodiment, the second DBR 23, the light emitting region 22 and a lateral part of the first DBR 21 are surrounded by the insulation layer 30; and the area defined by the extension from the two ends of the insulation layer 30 is 26 μm.

In a use of the preferred embodiment, the center area on top of the second DBR 23 has multiple crystalline layers, whose diameters are 3˜15 μm. Therein, when being used in a single-mode fiber, the diameter is 3˜6 μm; and, when being used in a multi-mode fiber, the diameter is 6˜15 μm. The diffusion structure 231 around the center area on the top of the second DBR 32 has a depth of 0.5˜3.0 μm. The diffusion structure 231 is selectively disordered with zinc (Zn), magnesium (Mg) or a II or IV or VI group element through selective doping and diffusion. Besides, the diffusion structure 231 around the center area on the top of the second DBR 32 is located above the light emitting region 22 and is not contact with the light emitting region 22, as shown in FIG. 1.

In a use of the preferred embodiment, the extended structure 20 is grown on a semi-insulated GaAs substrate 10. The first DBR 21 is 30 pairs of alternating Al_{0.9}Ga_{0.1}As/Al_{0.12}Ga_{0.88}As and the light emitting region 22 contained MQWs of GaAs/Al_{0.3}Ga_{0.7}As. A layer of Al_{0.98}Ga_{0.02}As formed into the undercut structure 24 is located above the light emitting region 22 (MQWs) with a distance more than 100 nm in-between. The second DBR 23 above is 20 pairs of alternating Al_{0.9}Ga_{0.1}As/Al_{0.12}Ga_{0.88}As.

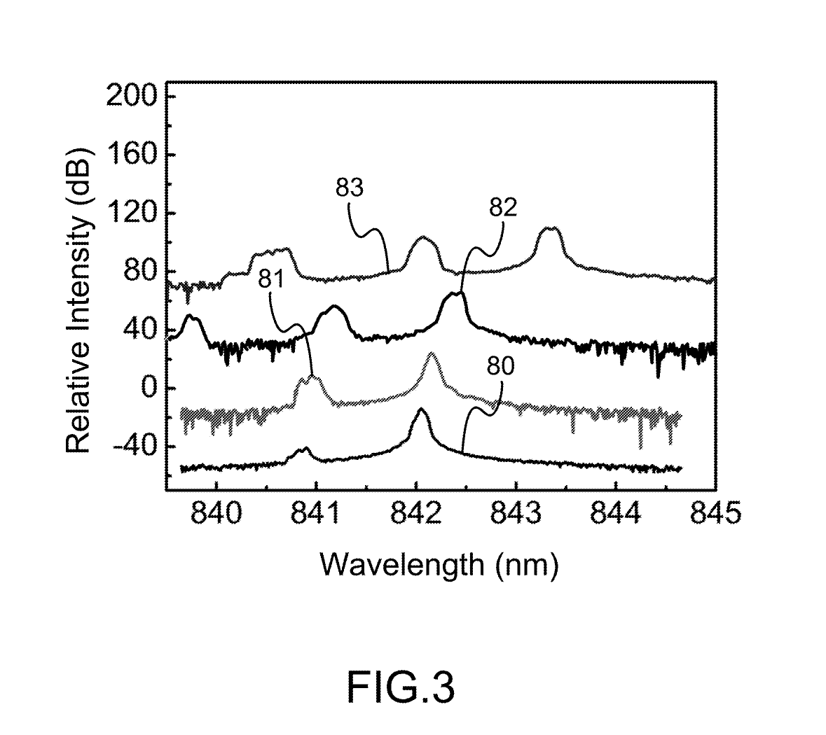

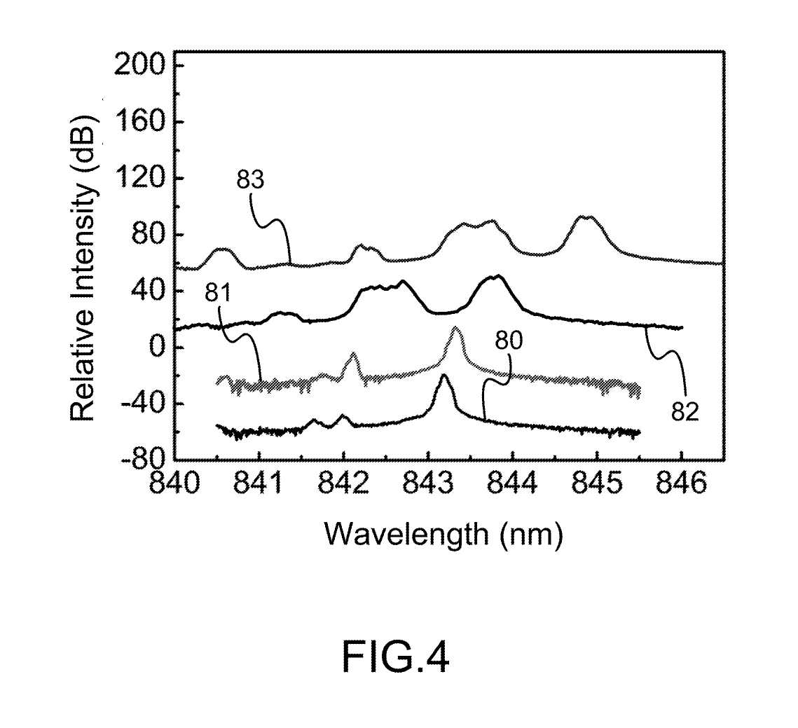

Please refer to FIG. 3 and FIG. 4, which are views showing first and second spectrums. As shown in the figures, with various sizes of Zn diffusion structure, DBR is formed on top of a VCSEL. Since the DBR is disordered after the diffusion of Zn, resistance is further reduced. Besides, depth of the Zn diffusion can be controlled to change a number of lasing modes for impacting a transferring rate.

In FIG. 3, a size and a depth of Zn diffusion are 6 μm and ˜1 μm, respectively. When the Zn diffusion size is 6 μm and the diffusion depth is more than 1.5 μm, a stable single mode output for an 850 nm VCSEL is ensured. During a high-speed transmission, the single mode output reduces mode dispersion of fiber and enhances the high speed transmission distance. Yet, the use in FIG. 3 has a Zn diffusion depth smaller than 1 μm to avoid pure single-mode characteristics and to balance between a highest modulation speed and a fiber transmission distance. However, in the other hand, for further reducing differential resistance of VCSEL and increasing bandwidth of resistance-capacitance (RC) limit, a deeper Zn diffusion depth is required. In FIG. 4, for avoiding pure single-mode characteristics, a Zn diffusion depth of 1.5 μm is used. But, with a larger size of light emitting aperture 301 (10 μm), a differential resistance of the use in FIG. 3 larger than that of the use in FIG. 4 can be expected.

The uses shown in FIG. 3 and FIG. 4 realize a differential resistance smaller than 140 ohms (Ω) under a bias current of 6 milliampere (mA). For an operation under 25 giga-bits per second (Gbit/sec), this value is smaller than that of a standard high-speed VCSEL. As shown by spectrum curves 80,81,82 under different bias currents of 0.6 mA, 1 mA, 2 mA and 4 mA, these two uses have similar single-mode behaviors. In the other hand, when the bias current is further increased, the uses both show multi-mode characteristics and the use in FIG. 4 has a greater number of optical modes owing to a larger size of the light emitting aperture 301. Besides, under the same data transmission rate (25 Gbit/sec), an error-protected-transmission distance of the use in FIG. 3 is 0.8 kilometers (km) and the use in FIG. 4 is 0.1 km, which shows that the use in FIG. 3 has a longer error-protected-transmission distance than the use in FIG. 4. By using the present invention having a mode control cavity to control the allowed lasing modes, the high speed transmission distance can be greatly enhanced.

The present invention is a VCSEL having a high speed (40 Gbit per second) and super-low power consumption. The present invention has an undercut structure and a diffusion structure to dissolve limits of oxide aperture in traditional VCSEL. By selectively removing a single layer in the VCSEL, parasitic capacitance is reduced and D-coefficient and biggest modulation speed are enhanced. Besides, for further reducing resistance, Zn diffusion is used in DBR to increase a number of lasing modes in the VCSEL, so that an E-O bandwidth and a bit-rate transmission distance in OM4 fiber can reach their largest values. Thus, a novel dynamic performance of VCSEL is obtained with an aperture having current threshold, where the aperture has a size about 5 μm and a best Zn diffusion depth. The present invention realizes a biggest D-coefficient (˜13.5 GHz/mA^{1/2}), a smallest energy-data rate under 34 Gbit/s (EDR:140 fJ/bit) and a smallest energy-data distance rate under 25 Gbit/s with 0.8 km of OM4 fiber (EDDR:175.5 fJ/bit·km).

To sum up, the present invention is a VCSEL having a mode control cavity to control the number of lasing modes and an undercut structure to confine the current. The VCSEL is operated under a 40 Gbit/s speed with super-low power consumption through the mode control cavity and the undercut structure, and the present invention obtains largest values of an electrical-optical bandwidth and a bit-rate transmission distance in OM4 fiber by controlling the number of lasing modes and having a good current confinement from undercut structure.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A vertical-cavity surface-emitting laser (VCSEL) having a mode control cavity to control the number of lasing modes and an undercut structure to confine the current, comprising
a substrate; and
an extended structure, said extended structure being grown on said substrate, said extended structure comprising
a first distributed Bragg reflector (DBR);
a light emitting region, said light emitting region being grown on said first DBR; and
a second distributed Bragg reflector (DBR), said second DBR being grown on said light emitting region,
wherein said light emitting region has an undercut structure; said undercut structure is located at a position selected from a group consisting of a position above said light emitting region and a position below said light emitting region; said undercut structure has a composite layer; a lateral part of said composite layer is etched to obtain a central current-confined area; and
wherein said second DBR has a mode control cavity with a diffusion structure surrounding a central area as a light emitting aperture; said diffusion structure is located in the periphery around said light emitting aperture on an end surface of said second DBR; said diffusion structure is a single layer; said single layer is obtained from a multi-layer selectively disordered through selective doping or diffusion; while said central area or said light emitting aperture remains in multi-layer.

2. The VCSEL according to claim 1,
Wherein said composite layer has a group III/V element having a content rate more than 20 percents (%); and said group III/V element is aluminum (Al);

3. The VCSEL according to claim 1,
wherein said first DBR is an n-type DBR (n-DBR) and said second DBR is a p-type DBR (p-DBR).

4. The VCSEL according to claim 1,
wherein said first DBR is a p-DBR and said second DBR is an n-DBR.

5. The VCSEL according to claim 1,
wherein a part of said composite layer is changed into an oxide layer with the rest of said composite layer kept same and said oxide layer is etched out through selective-etching to obtain said undercut structure and said current-confined area

6. The VCSEL according to claim 5,
wherein said oxide layer is etched out by using an etching solution to obtain said undercut structure and said current-confined area through selective-etching.

7. The VCSEL according to claim 1,
wherein said current-confined area is a circular surrounding area and has a diameter smaller than 5 micrometers (μm).

8. The VCSEL according to claim 1,
wherein said substrate is a semi-insulating semiconductor.

9. The VCSEL according to claim 8,
wherein said semi-insulating semiconductor is selected from a group consisting of gallium arsenide (GaAs), indium phosphide (InP), aluminum nitride (AlN), indium nitride (InN) and silicon (Si).

10. The VCSEL according to claim 1,
wherein said light emitting region is a heterojunction consisting of a compound semiconductor and an alloy of said compound semiconductor.

11. The VCSEL according to claim 10,
wherein said heterojunction is indium aluminum gallium arsenide/aluminium gallium arsenide (InAlGaAs/AlGaAs).

12. The VCSEL according to claim 1,
wherein said light emitting region comprises a structure of multiple quantum wells (MQWs); each MQW is made of InAlGaAs/AlGaAs; and said light emitting region is located between said first DBR and said second DBR.

13. The VCSEL according to claim 1,
wherein said second DBR, said light emitting region and a lateral part of said first DBR are surrounded by said insulation layer.

14. The VCSEL according to claim 1,
wherein said diffusion structure around said center area on said end surface of said second DBR has a depth between 0.5 μm and 3.0 μm.

15. The VCSEL according to claim 1,
wherein said mode control cavity has said light emitting aperture of diameter between 3 μm and 15 μm.

16. The VCSEL according to claim 1,
wherein said diffusion structure is obtained through diffusing an element selected from a group consisting of a group II element, a group IV element and a group VI element.

17. The VCSEL according to claim 16,
wherein said element is selected from a group consisting zinc (Zn) and magnesium (Mg).

18. The VCSEL according to claim 1,
wherein said diffusion structure is located above said light emitting region and is not contact with said light emitting region.
